(19) United States
(12) Patent Application Publication
(10) Pub. No.: US 2022/0287182 A1
(43) Pub. Date: Sep. 8, 2022

(54) EMBEDDED COMPONENT STRUCTURE AND MANUFACTURING METHOD THEREOF

(71) Applicant: Unimicron Technology Corp., Taoyuan City (TW)

(72) Inventors: Tzyy-Jang Tseng, Taoyuan City (TW); Yu-Hua Chen, Hsinchu City (TW); Chun-Hsien Chien, New Taipei City (TW); Wen-Liang Yeh, Hsinchu City (TW); Ra-Min Tain, Hsinchu County (TW)

(73) Assignee: Unimicron Technology Corp., Taoyuan City (TW)

(21) Appl. No.: 17/826,178

(22) Filed: May 27, 2022

Related U.S. Application Data
(63) Continuation-in-part of application No. 16/542,291, filed on Aug. 15, 2019.
Application No. 16/542,291 is a continuation-in-part of application No. 16/145,130, filed on Sep. 27, 2018.
(60) Provisional application No. 62/645,784, filed on Mar. 20, 2018.

(30) Foreign Application Priority Data
Jul. 27, 2018 (TW) 107126005
Jul. 2, 2019 (TW) 108123227

(51) Int. Cl. H05K 1/18; H05K 1/02; H05K 3/46

(52) U.S. Cl. CPC H05K 1/186; H05K 1/0298; H05K 1/183; H05K 3/4697

(57) ABSTRACT

An embedded component structure includes a board, an electronic component, and a dielectric material layer. The board has a through cavity. The board includes an insulating core layer and a conductive member. The insulating core layer has a first surface and a second surface opposite thereto. The through cavity penetrates the insulating core layer. The conductive member extends from a portion of the first surface along a portion of the side wall of the through cavity to a portion of the second surface. The electronic component includes an electrode. The electronic component is disposed in the through cavity. The dielectric material layer is at least filled in the through cavity. The connection circuit layer covers and contacts the conductive member and the electrode. A manufacturing method of an embedded component structure is also provided.

### CROSS-REFERENCE TO RELATED APPLICATION

This application is a continuation-in-part application of and claims the priority benefit of U.S. application Ser. No. 16/542,291, filed on Aug. 15, 2019, now pending. The prior U.S. application Ser. No. 16/542,291 is a continuation-in-part application of and claims the priority benefit of U.S. application Ser. No. 16/145,130, filed on Sep. 27, 2018, now pending, and Taiwan application serial no. 108123227, filed on Jul. 2, 2019. The prior U.S. application Ser. No. 16/145,130 claims the priority benefits of U.S. provisional application Ser. No. 62/645,784, filed on Mar. 20, 2018, and Taiwan application serial no. 107126005, filed on Jul. 27, 2018. The entirety of each of the above-mentioned patent applications is hereby incorporated by reference herein and made a part of this specification.

### BACKGROUND

### Technical Field

The disclosure relates to an electronic component and a manufacturing method thereof, and more particularly, to an embedded component structure and a manufacturing method thereof.

### Description of Related Art

In a typical embedded component structure, at least one conductive through via is used to electrically connect the electronic component to a printed circuit board (PCB). However, the above connection method makes the electrical transmission path between the electronic component and the printed circuit board long. The power and/or signal of the electronic product might be decreased, and the noise might be increased, thus the S/N ratio might be decreased and the quality of the electronic product might be reduced. Moreover, the manufacturing process of the above embedded component structure is more complicated and has a thicker thickness.

### SUMMARY

The disclosure provides an embedded component structure and a manufacturing method thereof, the thickness may be thinner and the manufacturing method may be relatively simple.

An embedded component structure provided in an embodiment of the invention includes a board, an electronic component, and a dielectric material layer. The board has a through cavity. The board includes an insulating core layer and a conductive member. The insulating core layer has a first surface and a second surface opposite thereto. The through cavity penetrates the insulating core layer. The conductive member extends from a portion of the first surface along a portion of the side wall of the through cavity to a portion of the second surface. The electronic component includes an electrode. The electronic component is disposed in the through cavity. The dielectric material layer is at least filled in the through cavity. The connection circuit layer covers and contacts the conductive member and the electrode.

A manufacturing method of an embedded component structure provided in an embodiment of the invention includes the following steps: providing a board, having a through cavity, and the board comprising: an insulating core layer, having a first surface and a second surface opposite thereto, wherein the through cavity penetrates the insulating core layer; and a conductive member, extending from a portion of the first surface along a portion of the side wall of the through cavity to a portion of the second surface; disposing an electronic component in the through cavity of the board, wherein the electronic component includes an electrode; forming a dielectric material layer at least filled in the through cavity; and forming a connection circuit layer covered and contacted the conductive member and the electrode.

To make the above features and advantages provided in one or more of the embodiments of the disclosure more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification.

The drawings illustrate embodiments of the disclosure and, together with the description, serve to explain the principles described herein.

FIGS. 1A to FIG. 1E are schematic top or bottom views of a manufacturing method of an embedded component structure according to an embodiment of the invention.

FIGS. 2A to FIG. 2E are schematic cross-sectional views of a manufacturing method of an embedded component structure according to an embodiment of the invention.

FIGS. 3A and 3B are schematic cross-sectional views of an embedded component structure according to an embodiment of the invention.

FIG. 4A is a schematic top view of a portion of an embedded component structure according to an embodiment of the invention.

FIG. 4B is a schematic perspective view of a portion of an embedded component according to an embodiment of the invention.

### DESCRIPTION OF THE EMBODIMENTS

In the following detailed description of the embodiments, reference is made to the accompanying drawings which form a part hereof, and in which are shown by way of illustrating specific embodiments in which the invention may be practiced. In this regard, directional terminology, such as “top,” “bottom,” “front,” “back,” “left,” “right,” etc., is used with reference to the orientation of the Figure(s) being described. The components provided in one or some embodiments of the invention may be positioned in a number of different orientations.

In the detailed description of the embodiments, the terms “first”, “second”, “third”, “fourth” and the like may be used to describe different elements. These terms are only used to distinguish elements from each other, but in the structure, these elements may not be limited by these terms. For example, a first element may be referred to as a second element, and similarly, a second element may be referred to as a first element without departing from the scope of the inventive concept. In addition, in the manufacturing method, the formation of these elements or components may not be limited by these terms except for a specific process flow. For example, the first element may be formed before the second element. Or, the first element may be formed after the second element. Alternatively, the first element and the second element may be formed in the same process or step.

The thickness of layer(s) or region(s) in the drawings may be exaggerated for clarity. Identical or similar devices are given identical or similar reference numerals in any of the following embodiments.

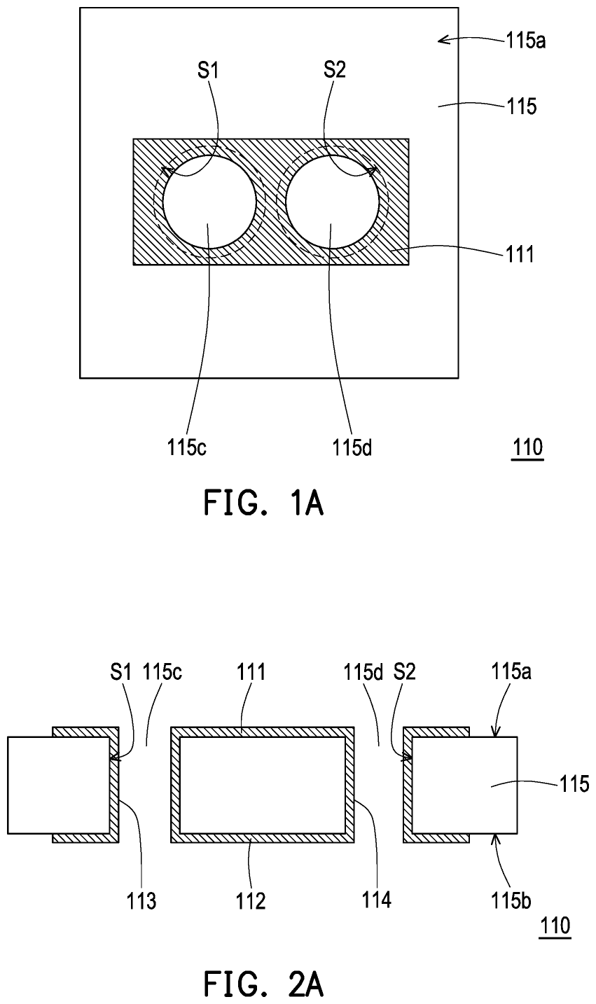

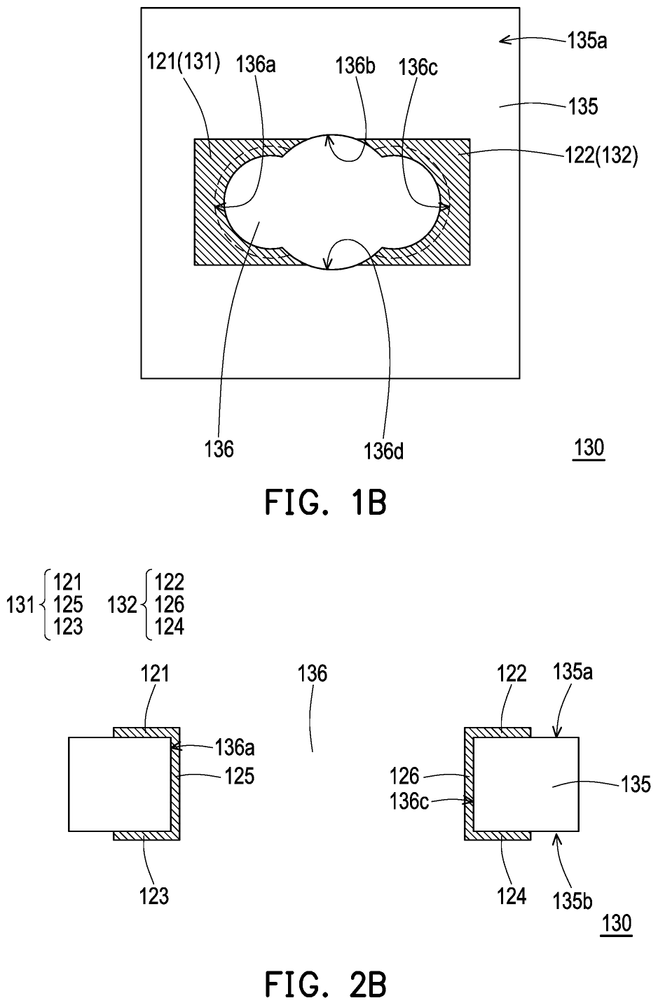

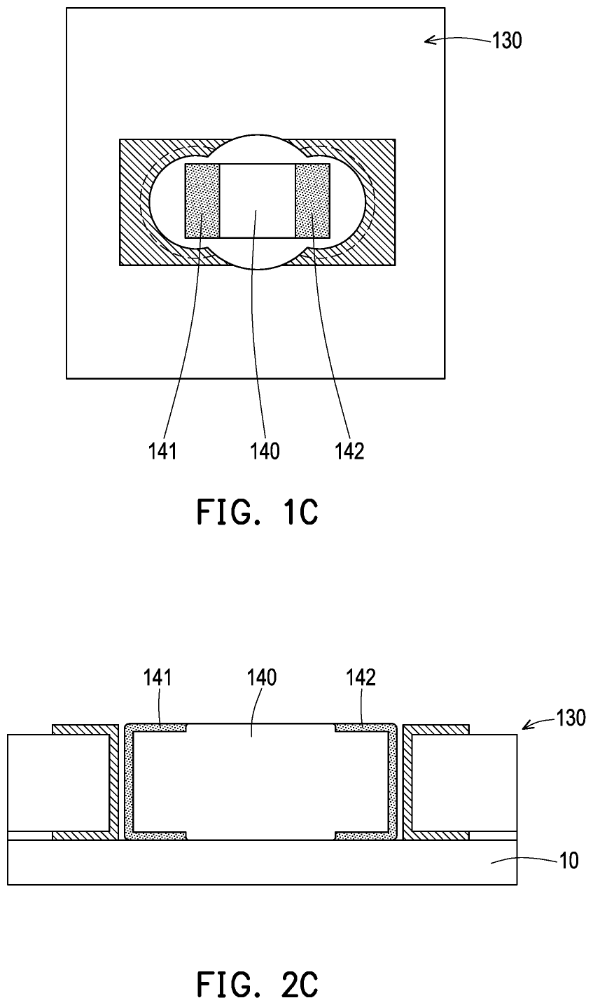

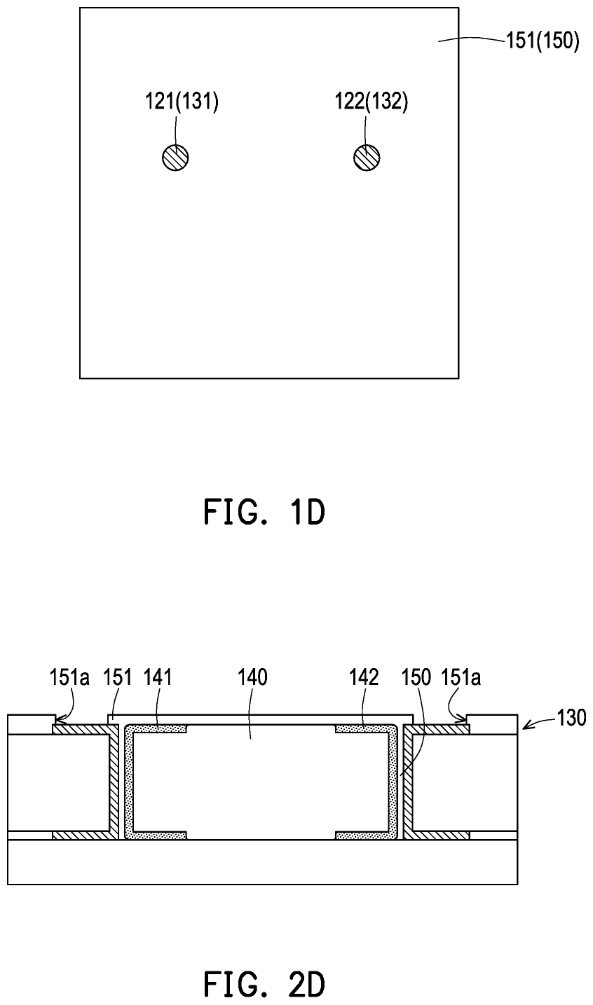

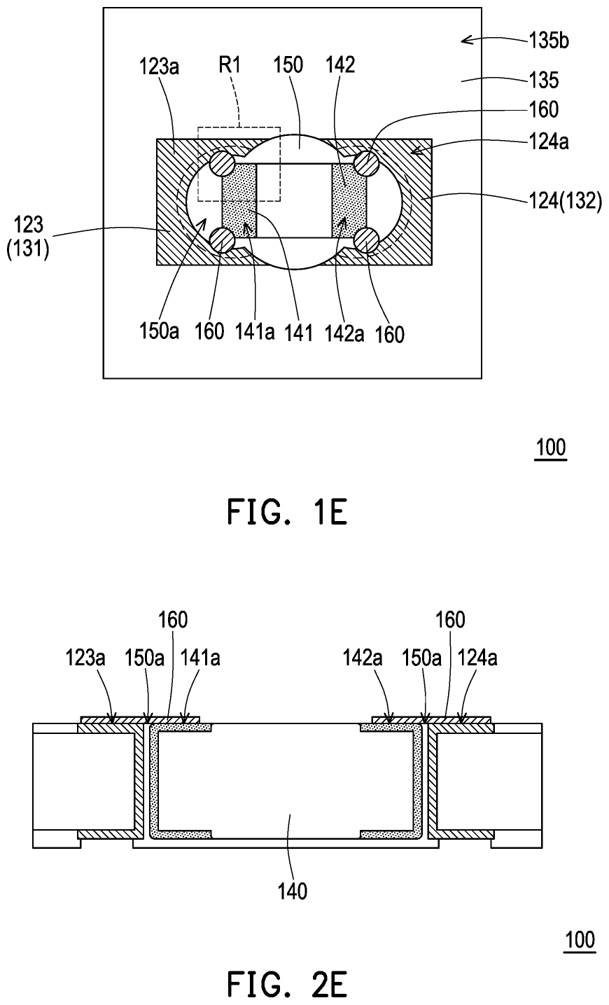

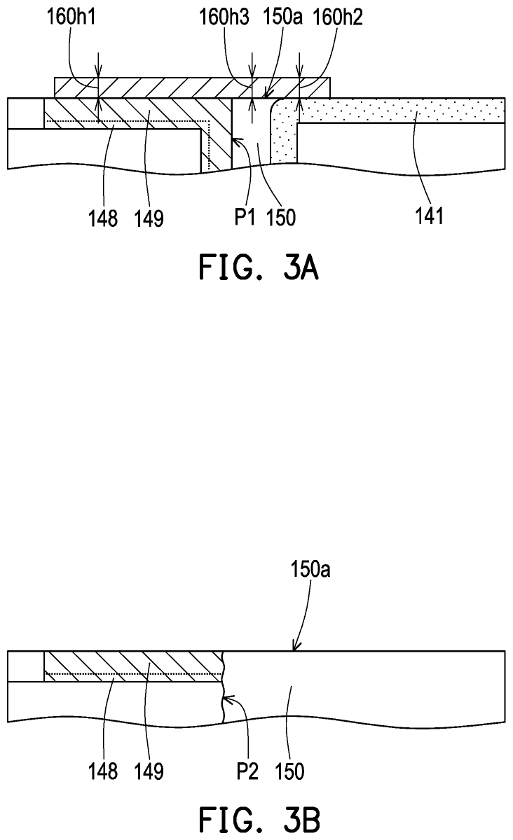

FIGS. 1A to FIG. 1E are schematic top or bottom views of a manufacturing method of an embedded component structure according to an embodiment of the invention. FIGS. 2A to FIG. 2E are schematic cross-sectional views of a manufacturing method of an embedded component structure according to an embodiment of the invention. FIGS. 3A and 3B are schematic cross-sectional views of an embedded component structure according to an embodiment of the invention. FIG.

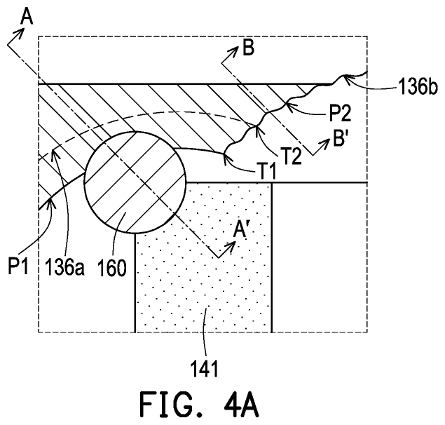

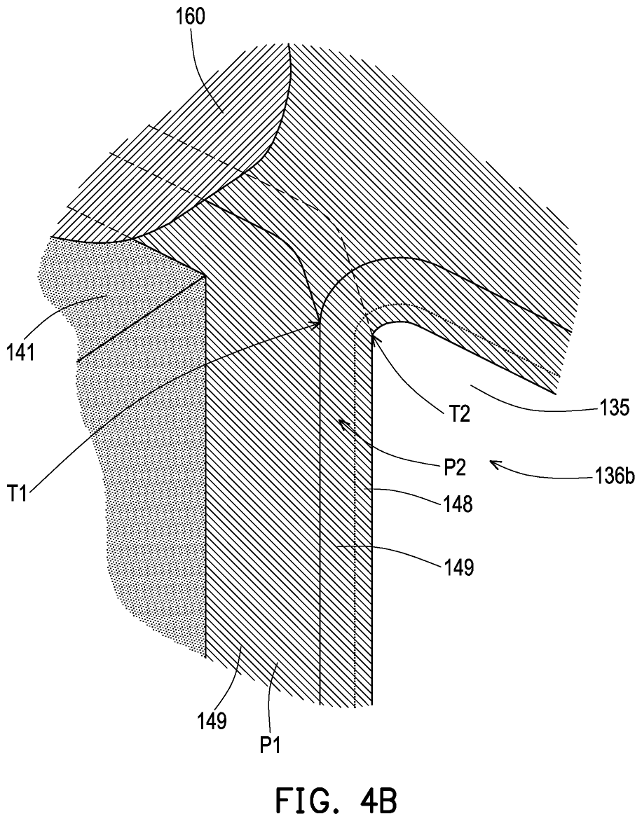

4A is a schematic top view of a portion of an embedded component structure according to an embodiment of the invention. FIG. 4B is a schematic perspective view of a portion of an embedded component according to an embodiment of the invention.

Referring to FIGS. 1A and 2A, a board 110 is provided. The board 110 includes a first conductive layer 111, a second conductive layer 112, a third conductive layer 113, a fourth conductive layer 114 and an insulating core layer 115. The insulating core layer 115 has a first surface 115a and a second surface 115b opposite thereto. A first through hole 115c and a second through hole 115d, which are structurally separated from each other, penetrate the insulating core layer 115, respectively. In other words, a side wall S1 of the first through hole 115c and a side wall S2 of the second through hole 115d are not connected to each other and are substantially perpendicular to the first surface 115a and/or the second surface 115b. The first conductive layer 111 is disposed on the first surface 115a. The second conductive layer 112 is disposed on the second surface 115b. The third conductive layer 113 is disposed on the side wall S1 of the first through hole 115c. The fourth conductive layer 114 is disposed on the side wall S2 of the second through hole 115d.

In an embodiment, the board 110 may be referred as a hard PCB (printed circuit board) or a hard board.

In an embodiment, the insulating core layer 115 of the circuit board 110 is made of a material having a higher Young's modulus. Thus, during the fabrication of the embedded component structure 100 (labeled in FIGS. 1E or 2E), the insulating core layer 115 or a properly physically processed derivative thereof (e.g., an insulating core layer 135 of a board 130 labeled in FIGS. 1B and/or 2B) may be used as a support for the manufacturing process or the overall final structure.

In an embodiment, the Young's modulus of the insulating core layer 115 may be greater than or equal to 70 Gigapascal (GPa).

In an embodiment, the material of the insulating core layer 115 is an insulator. For example, the material of the insulating core layer 115 may be ceramic or fiber-reinforced plastics (e.g., carbon-fiber-reinforced plastics (CFRP)), but the invention is not limited thereto.

In an embodiment, the material constituting the insulating core layer 115 does not include metal.

In an embodiment, the first conductive layer 111, the second conductive layer 112, the third conductive layer 113, and the fourth conductive layer 114 are the same and continuous film layer. The aforementioned film layer may include a seed layer directly contacting a portion of the outer surface of the insulating core layer 115 and a plating layer disposed on and covering the aforementioned seed layer. That is, in the structure of the board 110, the aforementioned seed layer is sandwiched between the aforementioned plating layer and the insulating core layer 115, and the aforementioned seed layer is not exposed to the outside.

In other regions not shown in FIGS. 1A or 2A, there may be other circuit on the first surface 115a or on the second surface 115b. The aforementioned circuit may be a same or similar film layer as the first conductive layer 111, the second conductive layer 112, the third conductive layer 113, and the fourth conductive layer 114.

In other regions not shown in FIGS. 1A or 2A, there may be a conductive via for electrically connecting a corresponding circuit disposed on the first surface 115a and a corresponding circuit disposed on the second surface 115b.

In an embodiment, from a top view (e.g., viewed along a normal direction of the first surface 115a and/or a normal direction of the second surface 115b, as shown in FIG. 1A), a shape of the first through hole 115c and/or the second through hole 115d may be circular.

Referring to FIGS. 1A to 1B and/or FIGS. 2A to 2B, a portion of the first conductive layer 111 (labeled in FIGS. 1A and/or 2A), a portion of the second conductive layer 112 (labeled in FIGS. 1A and/or 2A), a portion of the third conductive layer 113 (labeled in FIGS. 1A and/or 2A), a portion of the fourth conductive layer 114 (labeled in FIGS. 1A and/or 2A), and a portion of the insulating core layer 115 (labeled in FIGS. 1A and/or 2A) are removed, and a through cavity 136 (labeled in FIGS. 1B and/or 2B) is formed. For example, the removal step includes: removing the portion of the first conductive layer 111, the portion of the second conductive layer 112, the portion of the third conductive layer 113, the portion of the fourth conductive layer 114, and the portion of the insulating core layer 115 between the first through hole 115c and the second through hole 115d; as such, the aforementioned portion of the first conductive layer 111 being removed for forming a first conductive portion 121 and a second conductive portion 122 structurally separated from each other, the aforementioned portion of the second conductive layer 112 being removed for forming a third conductive portion 123 and a fourth conductive portion 124 structurally separated from each other, the aforementioned portion of the third conductive layer 113 being removed for forming a fifth conductive portion 125, the aforementioned portion of the fourth conductive layer 114 being removed for forming a sixth conductive portion 126, and the aforementioned portion of the insulating core layer 115 being removed for forming to an insulating core layer 135. That is, from a top view (e.g., as shown in FIGS. 1A and/or 1B), the region of the through cavity 136 at least covers the region of the first through hole 115c and the region of the second through hole 115d.

In an embodiment, after the aforementioned removal step, in the structure of the board 130, the seed layer is disposed between the plating layer and the insulating core layer 135, and a portion of the seed layer corresponding to the through cavity 136 is exposed to the outside.

In an embodiment, the aforementioned removal step may be performed by mechanical drilling or laser drilling. That is, a surface formed by the aforementioned removal step may be relatively rough (e.g., compared to a surface formed by plating).

Referring to FIGS. 1B and 2B, structurally, it may be considered that a board 130 includes an insulating core layer 135, a first conductive member 131, and a second conductive member 132. The insulating core layer 135 has a first surface 135a and a second surface 135b opposite thereto. A through cavity 136 penetrates the insulating core layer 135. The first conductive member 131 and the second conductive member 132 respectively extend from a portion of the first surface 135a along a portion of the side wall of the through cavity 136 to a portion of the second surface 135b.

For example, the side wall of the through cavity 136 has a first portion 136a, a second portion 136b, a third portion 136c, and a fourth portion 136d. The first conductive member 131 includes the first conductive portion 121, the fifth conductive portion 125, and the third conductive portion 123. The first conductive portion 121 is disposed on a portion of the first surface 135a, the third conductive portion 123 is disposed on a portion of the second surface 135b, and the fifth conductive portion 125 is disposed on the first portion 136a of the side wall of the through cavity 136.

In an embodiment, the seed layer of the first conductive member 131 near the second portion 136b and the fourth portion 136d is exposed to the outside.

For example, the side wall of the through cavity 136 has a first portion 136a, a second portion 136b, a third portion 136c, and a fourth portion 136d. The second conductive member 132 includes the second conductive portion 122, the sixth conductive portion 126, and the fourth conductive portion 124. The second conductive portion 122 is disposed on a portion of the first surface 135a, the fourth conductive portion 124 is disposed on a portion of the second surface 135b, and the sixth conductive portion 126 is disposed on the third portion 136c of the side wall of the through cavity 136.

In an embodiment, the seed layer of the second conductive member 132 near the second portion 136b and the fourth portion 136d is exposed to the outside.

In an embodiment, there is no conductor disposed on the second portion 136b and/or the fourth portion 136d of the side wall of the through cavity 136 substantially.

In an embodiment, the entire sidewall of the through hole 136 is consisted of the first portion 136a, the second portion 136b, the third portion 136c, and the fourth portion 136d. In other words, from a top view (e.g., as shown in FIG. 1B), the first portion 136a, the second portion 136b, the third portion 136c, and the fourth portion 136d form a closed shape.

In an embodiment, from a top view (e.g., as shown in FIG. 1B), a shape of the second portion 136b and the fourth portion 136d may correspond to different portions of a same circle.

In an embodiment, from a top view (e.g., as shown in FIG. 1B), a shape of the second portion 136b and the fourth portion 136d may correspond to different portions of a first circle, a shape of the first portion 136a may correspond to a portion of a second circle, a shape of the third portion 136c may correspond to a portion of a third circle, and the radius of the first circle is greater than the radius of the second or third circle.

Referring to FIGS. 1B to 1C and FIGS. 2B to 2C, an electronic component 140 is disposed on the carrier 10. For clarity, the elements/portions/surfaces of the board 130 are not labelled one by one in FIGS. 1C and 2C, and the elements/portions/surfaces of the board 130 may be referred to FIGS. 1B and 2B.

In an embodiment, the board 130 may be disposed on a carrier 10, then, the electronic component 140 is disposed on the carrier 10, and the electronic component 140 is embedded in the through cavity 136, but the invention is not limited thereto. In an embodiment, the electronic component 140 may be disposed on the carrier 10, then, the board 130 may be disposed on the carrier 10, and the through cavity 136 may be aligned with the electronic component 140 to embed the electronic component 140 into the through cavity 136.

In an embodiment, the electronic component 140 includes an electrode. For examples, the electronic component 140 includes a first electrode 141 and a second electrode 142.

In the embodiment, after the electronic component 140 being embedded in the through cavity 136, the electrical connection surface of the electrode of the electronic component 140 at least faces the carrier 10.

In an embodiment, the electronic component 140 may be multi-layer ceramic capacitor (MLCC), but the invention is not limited thereto.

The maximum thickness of the electronic component 140 may be greater than, equal to, or less than the maximum thickness of the board 130. For example, a thickness of a 0402 series MLCC (0402 MLCC) is about 500 μm, and a thickness of a 0603 series MLCC (0603 MLCC) is about 800 μm.

In an embodiment, the carrier 10 may a tap or a polymer film, but the invention is not limited thereto. In an embodiment, the carrier 10 may include a corresponding release material (e.g., a release film).

In the step as shown in FIGS. 1C and/or 2C, there may be a gap between the electronic component 140 and the side wall of the through cavity 136 (or, the conductive portion disposed thereon). That is, in the step as shown in FIGS. 1C and/or 2C, the electronic component 140 does not directly touch the board 130 substantially.

Referring to FIGS. 1C to 1D and FIGS. 2C to 2D, a dielectric material layer 150 is formed on the carrier 10, and the dielectric material layer 150 is at least filled in the through cavity 136 (labelled in FIG. 1B or 2B). For clarity, the elements/portions/surfaces of the board 130 are not labelled one by one in FIGS. 1D and 2D, and the elements/portions/surfaces of the board 130 may be referred to FIGS. 1B and 2B.

In the embodiment, the portion of the dielectric material layer 150 filled in the through cavity 136 may directly contact the fifth conductive portion 125 disposed on the first portion 136a, the second portion 136b without any conductor directly disposed thereon, the sixth conductive portion 126 disposed on the third portion 136c, the fourth portion 136d without any conductor directly disposed thereon. That is, the portion of the dielectric material layer 150 filled in the through cavity 136 may directly contact an outer surface of the seed layer of the first conductive member 131, and the portion of the dielectric material layer 150 filled in the through cavity 136 may directly contact an outer surface of the seed layer of the second conductive member 132.

For example, the portion of the dielectric material layer 150 filled in the through cavity 136 may directly contact an outer surface of the seed layer of the fifth conductive portion 125/ near the second portion 136b and the fourth portion 136d, and the portion of the dielectric material layer 150 filled in the through cavity 136 may directly contact an outer surface of the seed layer of the sixth conductive portion 126 near the second portion 136b and the fourth portion 136d.

In the embodiment, for example, a resin (i.e., epoxy or other similar thermosetting cross-linked resin), silane (i.e., hexamethyldisiloxane (HMDSN), tetraethoxysilane (TEOS), bis(dimethylamine)dimethylsilane (BDMADMS)) or other suitable dielectric material is coated on the carrier 10 and cured, and to be formed the dielectric material layer 150. In general, the aforementioned dielectric materials may have better adhesion and may have a lower (compared to the insulating core layer 135) Young's modulus. For example, the Young's modulus of the epoxy resin may be less than 5 GPa, and the Young's modulus of the silicone can be less than 1 GPa. That is to say, in the structure illustrated in FIGS. 1D and/or 2D, the entire structure may be supported by the insulating core layer 135 basically.

In an embodiment, the Young's modulus of the dielectric material layer 130 may be less than or equal to 10 Gigapascal (GPa).

In the embodiment, the dielectric material layer 150 is filled in the through cavity 136 and disposed between the electronic component 140 and the board 130. Since the dielectric material layer 150 may be formed of a material having a lower Young's modulus (compared to the insulating core layer 135), the dielectric material layer 150 may be provided as a buffer between the electronic component 140 and the board 130. In addition, in an embodiment, the electronic component 140 may be further fixed in the through cavity 136 via the dielectric material layer 150.

In an embodiment, the dielectric material layer 150 filled in the through cavity 136 may contact the carrier 10, but the invention is not limited thereto.

In the embodiment, the dielectric material layer 150 may include a cover portion 151. The cover portion 151 is disposed outside the through cavity 136 and covers a portion of the first conductive member 131 or second conductive member 132.

In the embodiment, the cover portion 151 has at least one dielectric opening 151a. The dielectric opening 151a may expose a portion of the first conductive member 131 or second conductive member 132.

In an embodiment, the dielectric opening 131a may be formed by etching, grinding drilling, laser drilling, or other suitable process, but the invention is not limited thereto.

Referring to FIGS. 1D to 1E and FIGS. 2D to 2E, the structure of FIGS. 1D and/or 2D may be flipped upside down before or after the carrier 10 is removed. After the carrier 10 is removed, the connection circuit layer 160 is formed. For clarity, the elements/portions/surfaces of the board 130 are not labelled one by one in FIGS. 1D and 2D, and the elements/portions/surfaces of the board 130 may be referred to FIGS. 1B and 2B.

In the embodiment, in the structure illustrated in FIGS. 1E and/or 2E, the entire structure may be supported by the insulating core layer 135 basically.

In the embodiment, since the board 130 and the electronic component 140 are both disposed on the carrier 10 and in contact with the carrier 10, the electrical connection surface 123a of the third conductive portion 123 and the electrical connection surface 141a of the first electrode 141 may be substantially coplanar; and/or the electrical connection surface 124a of the fourth conductive portion 124 and the electrical connection surface 142a of the second electrode 142 may be substantially coplanar.

In the embodiment, if the dielectric material layer 150 is filled in the through cavity 136 (shown in FIGS. 1B or 2B) for contacting the carrier 10, the electrical connection surface 123a of the third conductive portion 123, the dielectric surface 150a of the dielectric material layer 150, and the electrical connection surface 141a of the first electrode 141 may be substantially coplanar; and/or the electrical connection surface 124a of the fourth conductive portion 124, the dielectric surface 150a of the dielectric material layer 150, and the electrical connection surface 142a of the second electrode 142 may be substantially coplanar.

In the embodiment, the connection circuit layer 160 is a patterned film layer including a portion covering and contacting an electrical connection surface of the conductive member (e.g., the first conductive member 131 or second conductive member 132) and an electrical connection surface of the electrode (e.g., the first electrode 141 or the second electrode 142) of the electronic component 140. In an embodiment, the connection circuit layer 160 may be formed by a redistribution layer process (RDL process) or other suitable patterned circuit process.

One of the exemplary processes for forming the connection circuit layer 160 may be briefly described below. First, a seed layer (not shown) may be formed on the board 130 by sputtering. The seed layer is conformal with the electrical connection surface of the conductive member, the dielectric surface 150a of the dielectric material layer 150, and the electrical connection surface of the electrode. A general seed layer includes a titanium layer and/or a copper layer. However, the actual material of the seed layer depends on the conductive material that will be subsequently formed on the seed layer, the invention is not limited thereto. Next, a photoresist layer (not shown) is formed on the seed layer. The photoresist layer covers a portion of the seed layer. The photoresist layer may be formed by a coating process, a lithography process and an etching process. The photoresist layer has at least one opening corresponding to the electrical connection surface of the conductive member, the dielectric surface 150a of the dielectric material layer 150, and the electrical connection surface of the electrode. The opening exposes a portion of the seed layer above the electrical connection surface of the conductive member, the dielectric surface 150a of the dielectric material layer 150, and the electrical connection surface of the electrode. After the photoresist layer is formed, a conductive material layer (not shown) may be formed on the seed layer exposed by the opening. The conductive material layer on the seed layer may be formed by electroplating. The material of the conductive material layer may be similar to the material of the seed layer, but the invention is not limited thereto. After forming the conductive material layer, the photoresist layer and a portion of the conductive material layer on the photoresist layer are removed. Next, another portion of the conductive material layer that has not been removed is used as a mask to remove a portion of the seed layer that is not covered by the another portion of the conductive material layer. As such, the seed layer that has not been removed and the layer of conductive material that has not been removed may constitute the connection circuit layer 160.

After the above manufacturing process is performed, an embedded component structure 100 provided in the present embodiment is substantially formed.

FIG. 1E is a schematic top view of a portion of an embedded component according to an embodiment of the invention. FIG. 2E is a schematic cross-sectional view of a portion of an embedded component according to an embodiment of the invention. FIG. 3A is a schematic cross-sectional view of a portion of an embedded component according to an embodiment of the invention. FIG. 3B is a schematic cross-sectional view of a portion of an embedded component according to an embodiment of the invention. FIG. 4A is a schematic cross-sectional view of a portion of an embedded component according to an embodiment of the invention. FIG. 4B is a schematic perspective view of a portion of an embedded component according to an embodiment of the invention. For example, FIG. 3A is a schematic cross-sectional view corresponding to the section line A-A′ as shown FIG. 4A. For example, FIG. 3B is a schematic cross-sectional view corresponding to the section line B-B′ as shown FIG. 4A. For example, FIG. 4A is a schematic cross-sectional view corresponding the region R1 as shown in FIG. 1E. For example, FIG. 4B is a schematic perspective view corresponding the region as shown in FIG. 4A. For convenient comparison, a turning point T1 of the conductive member (e.g., first conductive member 131) is labelled in FIGS. 4A and 4B respectively, and a turning point T2 of the insulating core layer 135 is labelled in FIGS. 4A and 4B respectively.

Referring to FIGS. 1E, 2E, 3A to 4B, the embedded component structure 100 described above includes a board 130, an electronic component 140, a dielectric material layer 150, and a connection circuit layer 160.

The board 130 has a through cavity 136. The board 130 includes an insulating core layer 135, a first conductive member 131, and second conductive member 132. The insulating core layer 135 has a first surface 135a and a second surface 135b opposite thereto. The through cavity 136 penetrates the insulating core layer 135. The first conductive member 131 and the second conductive member 132 respectively extend from a portion of the first surface 135a along a portion of the side wall of the through cavity 136 to a portion of the second surface 135b. The electronic component 140 is disposed in the through cavity 136. The electronic component 140 includes a plurality of electrodes 141, 142. The dielectric material layer 150 is at least filled in the through cavity 136. The Young's modulus of the insulating core layer 135 is greater than the Young's modulus of the dielectric material layer 150. A portion of the connection circuit layer 160 covers and contacts an electrical connection surface of the conductive member (e.g., the first conductive member 131 or second conductive member 132) and an electrical connection surface of the electrode (e.g., the first electrode 141 or the second electrode 142) of the electronic component 140 for electrically connected to the corresponding electrode (e.g., the electrodes 141 or the electrode 142) and the corresponding conductive member (e.g., the first conductive member 131 or the second conductive member 132).

In the embodiment, the dielectric material layer 150 is further filled between the first electrode 141 and the first conductive member 131, and/or between the second electrode 142 and the second conductive member 132.

In the embodiment, in the cross-sectional view, on a cross section perpendicular to the first surface 135a or the second surface 135b (e.g., as shown in FIG. 3A), the cross-sectional thickness 160h1 of the connection circuit layer 160 on the electrical connection surface of the conductive member (e.g., the first conductive member 131 or second conductive member 132), the cross-sectional thickness 160h 3 of the connection circuit layer 160 on the dielectric surface 150a of the dielectric material layer 150, and the cross-sectional thickness 160h2 of the connection circuit layer 160 on the electrical connection surface of the electrode (e.g., the first electrode 141 or the second electrode 142) of the electronic component 140 are substantially the same.

In the embodiment, taking a portion of the first conductive member 131 as shown in FIGS. 3A to 4B as an example, the conductive member (e.g., the first conductive member 131 or second conductive member 132) has an inside surface facing the electronic component 140. The inside surface has an inner portion P1 and an outer portion P2. From a top view (e.g., as shown in FIG. 1E), the outer portion P2 corresponds to the second portion 136b or the fourth portion 136d, and the inner portion P1 corresponds to the first portion 136a or the third portion 136c. Taking the first conductive member 131 as an example, from a top view (e.g., as shown in FIG. 4E), the outer portion P2 (e.g., from the turning point T1 to a nearest corresponding edge) aligned with the second portion 136b or the fourth portion 136d, and the inner portion P1 (e.g., between the two outer portions P2) is parallel to the first portion 136a. Similar, taking the second conductive member 132 as an example, from a top view, the outer portion P2 (e.g., from a turning point to a nearest corresponding edge) aligned with the second portion 136b or the fourth portion 136d, and the inner portion P1 (e.g., between the two outer portions P2) is parallel to the third portion 136c.

In the embodiment, from a top view (e.g., as shown in FIG. 1B), a shape of the outer portion P2 may be a portion of a first circle, a shape of the inner portion P1 may be a portion of a second circle, and the radius of the first circle is greater than the radius of the second circle.

In the embodiment, the inside surface of the conductive member (e.g., the first conductive member 131 or second conductive member 132) is completely covered by the portion of the dielectric material layer 150 filled in the through cavity 136.

In the embodiment, the surface roughness (Ra) of the inner portion P1 is smaller than that of the outer portion P2. For example, the inner portion P1 is a final-formed surface formed by electroplating process, and the outer portion P2 is a final-formed surface formed by drilling process.

In the embodiment, the inner portion P1 entirely consists of a portion of the outer surface of the plating layer 149, and the outer portion P2 is composed of a portion of the outer surface of the seed layer 148 and a portion of the outer surface of the plating layer 149. That is, the portion of the dielectric material layer 150 filled in the through cavity 136 may directly contact a portion of the outer surface of the seed layer 148 located in the outer portion P2.

Based on the above, the electronic component 140 and the board 130 are electrically connected via the connection circuit layer 160 therebetween, and a conductive via between the electronic component 140 and the board 130 could no need to be formed or omitted (not shown because none). Therefore, the manufacturing process of the embedded component structure 100 could be simpler and has a thinner thickness. In addition, the circuit path between the electronic component 140 and the board 130 may be reduced via the connection circuit layer 160, and the signal transmission time may be reduced, and the transmission rate between different electronic components may be improved. Moreover, the board 130 is not completely removed during the manufacturing process of the embedded component structure 100. Therefore, in the manufacturing method of the embedded component structure 100, the board 130 needs to have better supportability (e.g., by having the insulating core layer 135 having a higher Young's modulus).

In an embodiment not shown, the dielectric material layer 150 may have a dielectric opening that exposes the electronic component 140.

In an embodiment not shown, a heat dissipating component may be thermally coupled to the electronic component 140.

In an embodiment not shown, the electronic component 140 may be an optical sensing chip (e.g., a chip including a charge-coupled device (CCD)), an acoustic chip (e.g., a chip including a MEMS device), or a sensing chip suitable for receiving external signals.

In an embodiment not shown, there may be a cover layer disposed on the electronic component 140.

In an embodiment not shown, a redistribution structure may be disposed on the first surface 135a or the second surface 135b.

It will be apparent to those skilled in the art that various modifications and variations can be made to the structure described in the disclosure without departing from the scope or spirit of the disclosure. In view of the foregoing, it is intended that the disclosure cover modifications and variations provided they fall within the scope of the following claims and their equivalents.

What is claimed is:

1. An embedded component structure, comprising:
a board having a through cavity, and the board comprising:
an insulating core layer, having a first surface and a second surface opposite thereto, wherein the through cavity penetrates the insulating core layer; and
a conductive member, extending from a portion of the first surface along a portion of the side wall of the through cavity to a portion of the second surface;
an electronic component, including an electrode, wherein the electronic component is disposed in the through cavity and;
a dielectric material layer, at least filled in the through cavity; and
a connection circuit layer, covered and contacted the conductive member and the electrode.

2. The embedded component structure of claim 1, wherein the Young's modulus of the insulating core layer is greater than the Young's modulus of the dielectric material layer.

3. The embedded component structure of claim 1, wherein the through cavity has a side wall facing the electronic component, the side wall of the through cavity has a first portion, a second portion, a third portion, and a fourth portion, from a top view:
the first portion, the second portion, the third portion, and the fourth portion form a closed shape; and
a shape of the second portion and the fourth portion correspond to different portions of a first circle.

4. The embedded component structure of claim 3, there is no conductor directly disposed on the second portion and the fourth portion of the side wall of the through cavity.

5. The embedded component structure of claim 3, from the top view, a shape of the first portion corresponds to a portion of a second circle, a shape of the third portion corresponds to a portion of a third circle, and the radius of the first circle is greater than the radius of the second or third circle.

6. The embedded component structure of claim 1, wherein the conductive member has an inside surface facing the electronic component, the inside surface has two outer portions and an inner portion between the two outer portions, and a surface roughness of the inner portion is smaller than a surface roughness of the outer portions.

7. The embedded component structure of claim 1, wherein the conductive member includes a seed layer disposed on the insulating core layer and a plating layer disposed on the seed layer, the conductive member has an inside surface facing the electronic component, the inside surface has two outer portions and an inner portion between the two outer portions, the inner portion entirely consists of a portion of an outer surface of the plating layer, and the two outer portion is composed of a portion of an outer surface of the seed layer and a portion of the outer surface of the plating layer.

8. The embedded component structure of claim 1, wherein the conductive member includes a seed layer disposed on the insulating core layer and a plating layer disposed on the seed layer, and the dielectric material layer filled in the through cavity directly contact a portion of the seed layer.

9. The embedded component structure of claim 1, wherein the conductive member includes a seed layer disposed on the insulating core layer and a plating layer disposed on the seed layer, the conductive member has an inside surface facing the electronic component, the inside surface has two outer portions and an inner portion between the two outer portions, the inner portion entirely consists of a portion of an outer surface of the plating layer, the two outer portion is composed of a portion of an outer surface of the seed layer and a portion of the outer surface of the plating layer, and the dielectric material layer filled in the through cavity directly contact the portion of the outer surface of the seed layer located in the two outer portions.

10. The embedded component structure of claim 1, wherein the connection circuit layer covers and contacts the dielectric material layer being filled between the electrode and the conductive member, and on a cross section perpendicular to the first electrical connection surface, a cross-sectional thickness of the connection circuit layer on the electrode, a cross-sectional thickness of the connection circuit layer on the dielectric surface being filled between the electrode and the conductive member, and a cross-sectional thickness of the connection circuit layer on the conductive member are substantially the same.

11. The embedded component structure of claim 1,
wherein the Young's modulus of the insulating core layer is greater than the Young's modulus of the dielectric material layer,
wherein the through cavity has a side wall facing the electronic component, the side wall of the through cavity has a first portion, a second portion, a third portion, and a fourth portion,
wherein from a top view:
the first portion, the second portion, the third portion, and the fourth portion form a closed shape;
a shape of the second portion and the fourth portion correspond to different portions of a first circle;
a shape of the first portion corresponds to a portion of a second circle, a shape of the third portion corresponds to a portion of a third circle, and the radius of the first circle is greater than the radius of the second or third circle; and
there is no conductor directly disposed on the second portion and the fourth portion of the side wall of the through cavity,
wherein the conductive member includes a seed layer disposed on the insulating core layer and a plating layer disposed on the seed layer, the conductive member has an inside surface facing the electronic component, the inside surface has two outer portions and an inner portion between the two outer portions, the inner portion entirely consists of a portion of an outer surface of the plating layer, the two outer portion is composed of a portion of an outer surface of the seed layer and a portion of the outer surface of the plating layer, a surface roughness of the inner portion is smaller than a surface roughness of the outer portions, and the dielectric material layer filled in the through cavity directly contact a portion of the seed layer,
wherein the connection circuit layer covers and contacts the dielectric material layer being filled between the electrode and the conductive member, and on a cross section perpendicular to the first electrical connection surface, a cross-sectional thickness of the connection circuit layer on the electrode, a cross-sectional thickness of the connection circuit layer on the dielectric surface being filled between the electrode and the conductive member, and a cross-sectional thickness of the connection circuit layer on the conductive member are substantially the same.

12. A manufacturing method of an embedded component structure, comprising:
providing a board, having a through cavity, and the board comprising:
an insulating core layer, having a first surface and a second surface opposite thereto, wherein the through cavity penetrates the insulating core layer; and
a conductive member, extending from a portion of the first surface along a portion of the side wall of the through cavity to a portion of the second surface;
disposing an electronic component in the through cavity of the board, wherein the electronic component includes an electrode;
forming a dielectric material layer at least filled in the through cavity, wherein the Young's modulus of the insulating core layer is greater than the Young's modulus of the dielectric material layer; and
forming a connection circuit layer covered and contacted the conductive member and the electrode.
